(19) United States
(12) Patent Application Publication
(10) Pub. No.: US 2009/0114887 A1
(43) Pub. Date: May 7, 2009

(54) Bulk, free-standing cubic III-N substrate and a method for forming same.

(76) Inventors: A. J. Kent, Nottingham (GB); S. V. Novikov, Nottingham (GB); N. M. Stanton, Hungerford (GB); R. P. Campion, Nottingham (GB); C. T. Foxon, Nottingham (GB)

Correspondence Address: HARRINGTON & SMITH, PC, 4 RESEARCH DRIVE, Suite 202, SHELTON, CT, 06484-6212, US

(21) Appl. No.: 11/920,110

(22) PCT Filed: May 5, 2006
(86) PCT No.: PCT/GB2006/001652

§ 371 Date: Dec. 15, 2008

(30) Foreign Application Priority Data
May 9, 2005 (GB) 0509328.1

(51) Int. Cl. H01B 1/00; C30B 25/02; C30B 25/16; C01B 21/06; B32B 5/00

(52) U.S. Cl. 252/521.5; 117/108; 117/105; 423/409; 428/220

(57) ABSTRACT

A method of forming a bulk, free-standing cubic III-N substrate including a) growing epitaxial III-N material on a cubic III-V substrate using molecular beam epitaxy (MBE); and b) removing the III-V substrate to leave the III-N material as a bulk, free-standing cubic III-N substrate. A bulk, free-standing cubic III-N substrate for fabrication of III-N devices.

### FIELD OF THE INVENTION

Embodiments of the invention relate to a method for forming a bulk, free-standing cubic III-N substrate and the substrate formed by the method. In particular, embodiments of the invention relate to cubic GaN substrates.

### BACKGROUND TO THE INVENTION

There is an increasingly high level of commercial and scientific interest in nitride semiconductors. The group III-nitrides (AIN, GaN and InN and their solid solutions) are being used increasingly for amber, green, blue and white light emitting diodes (LEDs), for blue/UV laser diodes (LDs) and for high-power, high-frequency and high temperature electronic devices.

One of the most severe problems hindering progress in the field of nitride technology is the lack of a suitable substrate material onto which lattice-matched group III-nitride films can be grown. Very high dislocation densities exist in group III-nitride films grown on the commonly used substrates of sapphire, GaAs or SiC, which are non-lattice matched substrates.

A composite substrate may be used to reduce the density of dislocations. A high quality GaN buffer layer may be grown on a SIC or sapphire substrate using metal-organic vapour phase epitaxy (MOVPE) or hydride vapour phase epitaxy (HVPE). However, GaN layers grown on GaN composite substrates still suffer both stress and defects.

Bulk, freestanding GaN substrates, which would be matched in lattice constant and thermal expansion properties to GaN films deposited on the substrate are consequently still needed in the fabrication of high-quality GaN-based devices.

In standard III-V systems it is possible to obtain big bulk crystals by the established growth from melt techniques such as Czochralski or Bridgman. Unfortunately, this is not possible for GaN due to its extremely high melting temperature and very high decomposition pressure at melting. Therefore GaN crystals have to be grown by other methods.

High quality bulk, freestanding wurtzite (hexagonal) GaN substrates can be grown from liquid Ga solutions. The solubility of N in Ga is increased using high pressures (12-15×10⁸ Pa) and high temperatures (1500-1600° C.) (Czernetzki R et al, 2003 Phys. Stat. Sol a 200 9; Grzegory I, et al., 2002 J. Cryst. Growth 246 177; Grzegory I et al 2001 Acta Physica Polonica A 100 57). However, such bulk freestanding GaN hexagonal crystals are still not commercially available mainly due to their small size and the cost of production.

For wurtzite group III-nitrides, the built-in electric fields arising from the piezo- and spontaneous polarizations are very significant (Ambacher O et al, 2002 J. Phys.: Condens. Matter 14 3399).

Studies have demonstrated that the growth of non-polar GaN may be crucial for achieving high emission efficiency and good transport properties in nitride device structures (Martinez C E et al, 2004 J. Appl. Phys. 95 7785; Belyaev A E et al, 2003 Appl. Phys. Lett 83 3626; and Novikov S V et al In Proc.: MRS Fall meeting, Boston, USA, Dec. 1-5, 2003, Y10.66, 661; Mat Res. Soc. Symp. Proc. 2004 798 533).

The polarization effects can be eliminated by growing either zinc-blende (cubic) III-nitride layers (the standard cubic orientation is (100)) or non-polar wurtzite (hexagonal) III-nitride layers. These wurtzite non-polar orientations include (11-20) a-plane or (1-100) m-plane wurtzite GaN, which can be grown on (11-20) a-plane or (1-102) r-plane sapphire and (100) LiAlO₂ substrates respectively.

### BRIEF DESCRIPTION OF THE INVENTION

It would be desirable to produce a bulk, free-standing cubic (zinc-blende) III-N substrate on which cubic II-N epitaxial layers can be grown.

According to one embodiment of the invention there is provided a method of forming a bulk, free-standing cubic III-N (e.g. GaN) substrate comprising: a) growing epitaxial III-N (e.g. GaN) material on a cubic III-V (e.g. GaAs) substrate using molecular beam epitaxy (MBE); and b) removing the III-V (e.g. GaAs) substrate to leave the III-N material as a bulk, free-standing cubic III-N substrate.

It is not obvious to use MBE in order to obtain a bulk free-standing cubic GaN substrate, as MBE is generally regarded as an undesirable method of crystal growth as it is very slow.

It is not obvious what sequence of steps are required and what parameters of the MBE process (Ga:N ratio, growth temperatures, buffer layers, steps sequence, etc) are required to avoid intensive cracking of a growing cubic GaN layer and thus allow one to obtain a bulk, free-standing cubic GaN substrate.

According to one embodiment of the invention there is provided a bulk, free-standing cubic III-N substrate for fabrication of III-N devices.

The bulk free standing substrate is typically a monocrystal. It may be of large area i.e. >1 cm² and large thickness i.e. >5 μm.

### DEFINITIONS

An epitaxial layer is a layer that has the same crystalline orientation as the substrate on which it is grown.

A bulk free-standing substrate is one which is not attached to any substrate i.e. is non-composite and is thick enough to be self-supporting and subsequently maneuvered in a device fabrication process.

### BRIEF DESCRIPTION OF THE DRAWINGS

For a better understanding of the present invention reference will now be made by way of example only to the accompanying drawings in which:

FIG. 1A illustrates a cubic III-V (e.g. GaAs) substrate;

FIG. 1B illustrates a cubic III-V (e.g. GaAs) substrate with a buffer layer of the same III-V material (e.g. GaAs);

FIG. 1C illustrates a composite substrate comprising epitaxial cubic III-N material (e.g. GaN) deposited on the III-V (e.g. GaAs) substrate; and

FIG. 1D illustrates a bulk, free-standing cubic III-N (e.g. GaN) substrate.

### DETAILED DESCRIPTION OF THE INVENTION

The description describes how an undoped cubic III-N monocrystal is grown by plasma-assisted molecular beam epitaxy (PA-MBE) on a semi-insulating GaAs (001) substrate and then freed from the GaAs to form a bulk, freestanding cubic III-N substrate that may be used in the subsequent fabrication of epitaxial III-N devices.

The monocrystal growth is performed in a standard MBE growth chamber. The MBE system has an Oxford Applied Research (OAR) CARS25 RF activated plasma source to provide the atomic nitrogen species required for the growth, and elemental gallium was used as the group III-source. A RHEED facility is used for surface reconstruction analysis and a quadrupole mass spectrometer for residual gas monitoring in the growth chamber. The growth chamber is pumped by both an ion-pump and a turbo pump. The nitrogen plasma source is operated at 200 to 450 Watts with a nitrogen flow rate of a few standard cubic centimetres per minute (sccm). The Ga and N fluxes were initially adjusted to establish growth under nominally stoichlometric conditions at the growth temperatures. The temperature of the substrate was measured by a pyrometer through a direct sight optical window and monitored by a thermocouple in the substrate holder.

The Oxford Applied Research (OAR) CARS25 RF activated plasma source is equipped with a silicon diode optical emission detector (OED). The signal from this OED is proportional to the amount of active nitrogen species coming from the source. Arsenic in the form of dimers (As₂) or tetramers (As₄) are produced using a two-zone purpose made cell, and the arsenic fluxes produced are in the range from 1×10⁻⁷ to 1×10⁻² Pa (BEP).

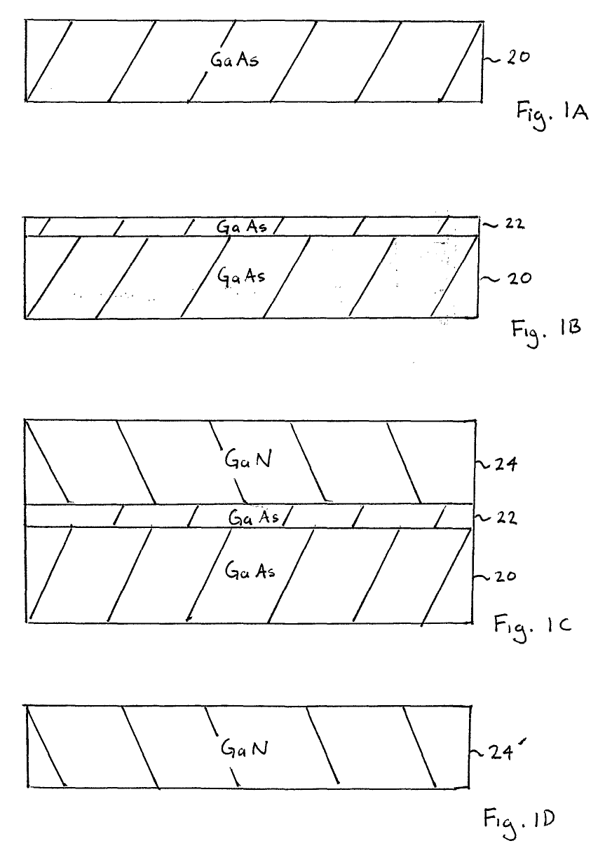

FIG. 1A illustrates an epi-ready semi-insulating cubic GaAs substrate 20 that has been loaded into the MBE system without any additional chemical treatment. Surface oxide is removed from the surface of the GaAs substrate by thermal heating to ˜550-700° C.

As illustrated in FIG. 1B, prior to the growth of GaN, a GaAs buffer layer 22 can optionally be grown on the GaAs substrate 20 in order to improve the quality of subsequently grown GaN films. The GaAs buffer epitaxial layer may be grown using MBE in the MBE chamber at temperatures between 550 and 700° C. under As-rich conditions with a low Ga:As ratio. The As flux was a few times higher than Ga. The Ga:As ratio and the growth temperatures can be optimised to achieve a flat GaAs surface, which can be identified by a 2×4 RHEED reconstruction.

As illustrated in FIG. 1C, a layer of epitaxial cubic GaN 24 is then grown on the GaAs. This layer is grown in a number of distinct stages each of which has carefully controlled MBE growth parameters.

### Stage 1: Initiation

During GaN growth initiation the MBE growth parameters are carefully controlled to avoid intensive cracking of the cubic GaN epitaxial layer 24.

The growth of the cubic (zinc-blende) GaN epitaxial layer 24 was initiated under the following MBE growth parameters:
a) N-rich conditions;
b) at a temperature between 550 and 700° C.; and
c) under co-impinging arsenic flux of 10⁻⁴-10⁻² Pa.

The nitrogen plasma source is operated at 200 to 450 Watts with the nitrogen flux resulting in a system pressure of 1 to 5×10⁻³ Pa beam equivalent pressure (BEP), corresponding to a nitrogen flow rate of a few standard cubic centimetres per minute (sccm).

The N-rich conditions are important because if one starts the growth under Ga-rich conditions hexagonal GaN will be obtained.

The temperature is important because growth at very low growth temperatures produces hexagonal GaN with GaAs inclusions or may even produce a GaAs layer instead of GaN.

Lower growth temperatures also result in surface roughness and a loss of structural quality. Growth at slightly higher temperatures than the range specified results in cracking of the GaN after a period of time and potentially in evaporation of a GaAs substrate.

The co-impinging As flux is important. If the As flux is too low the GaN layer will be hexagonal.

After GaN growth initiation the MBE growth parameters are carefully controlled to avoid intensive cracking of the cubic GaN epitaxial layer 24 and thus allow the growth of a thick epitaxial layer of GaN.

### Stage 2:Growth

The growth of the cubic (zinc-blende) GaN epitaxial layer 24 was continued under the following MBE growth parameters:
a) N-rich conditions;
b) the temperature was increased to between 600 and 740° C.; and
c) the As flux was terminated.

In some situations the As flux is maintained during the growth of GaN, but this is optional.

After 10-20 minutes, stage 3 may be entered.

### Stage 3: Controlled Growth

This stage is optional, but desirable, as it can be used to increase the growth rate of the GaN layer 24. The growth of the cubic (zinc-blende) GaN epitaxial layer 24 was continued under the following MBE growth parameters:
a) Ga:N ratio is used to control the growth rate. It may be slightly Ga-rich (but before the Ga droplet formation) or a different N-rich condition;
b) the temperature remains at between 600 and 740° C.; and
c) the As flux remains terminated.

In some situations the As flux is maintained during the growth of GaN, but this is optional.

The desired final thickness for the cubic GaN layer 24 can be obtained by continuing the growth under these conditions.

Cubic GaN layers with a thickness>5 μm and areas>1 cm² have been grown in a continuous MBE growth run or in a several MBE growth steps, which include switching off and on the Ga- and N-fluxes and cooling and heating of the substrate.

The thick layer 24 of GaN is converted to an undoped, bulk, free standing cubic (zinc-blende) GaN substrate 24′ by removing the GaAs 20, 22. This may, for example, be done using an H₃PO₄:H₂O₂ etch solution. The final bulk, free-standing cubic GaN substrate 24′ is illustrated in FIG. 1D. It is a monocrystal.

It should be realised that such a bulk, free-standing cubic GaN substrate 24′ can be realised only under specific MBE growth conditions.

The thickness of the bulk, freestanding cubic GaN substrate 24′ can be increased by either further increase of the growth time at stage 3 or by further GaN growth in a separate high-growth rate MBE system. Potentially we can increase the thickness of the cubic GaN before and/or after removal of the GaAs 22, 20.

The surface of the bulk, free-standing cubic GaN substrate 24′ may be mechanical-chemically polished in order to improve surface roughness, if present.

There is an inherent difficulty in precisely quantifying a Ga:N ratio for PA-MBE. Consequently at present descriptions of the Ga:N ratios in PA-MBE publications are still quite qualitative. MBE growth can take place under three distinctly different conditions:
i) N-rich growth where the active nitrogen flux is larger than the Ga-flux and the growth rate is determined by the arrival rate of Ga atoms.
ii) Ga-rich growth where the active nitrogen flux is less than the Ga-flux and the growth rate is determined by the arrival rate of active nitrogen.
iii) Strongly Ga-rich growth where the active nitrogen flux is much less than the Ga-flux and Ga droplets are formed on the surface.

In order to establish the proper growth conditions in a particular chamber for cubic GaN, the growth chamber is first calibrated by growing thin cubic GaN layers under different Ga:N ratios. For example, the Ga flux that allows growth under slightly Ga-rich growth conditions, but before the formation of the Ga droplets is identified.

The preceding paragraphs describe the formation of an undoped, bulk, free standing cubic (zinc-blende) III-N substrate 24′. Those skilled in the art will also appreciate that the above described techniques are also suitable for forming doped, bulk, free standing cubic (zinc-blende) III-N substrates.

To form a bulk, free-standing cubic III-N (e.g. GaN) substrate of a desired conductivity type and doping level the process continues as described above. However, in Stage 2: growth and also Stage 3:controlled growth (if used) a controlled flux of dopant is added in addition to the Ga and N flux. The level of doping is determined by the flux of the dopant species.

A p-type or semi-insulating bulk, free standing cubic (zinc-blende) III-N substrate may be achieved by using a solid source of p-type dopant such as Mn or a gaseous source of p-type dopant such as CBr₄ and CP₂Mn.

An n-type, free standing cubic (zinc-blende) III-N substrate may be achieved by using a solid source of n-type dopant such as Si, or a gaseous source of p-type dopant such as silane.

Although embodiments of the present invention have been described in the preceding paragraphs with reference to various examples, ft should be appreciated that modifications to the examples given can be made without departing from the scope of the invention as claimed.

Whilst endeavouring in the foregoing specification to draw attention to those features of the invention believed to be of particular importance it should be understood that the Applicant claims protection in respect of any patentable feature or combination of features hereinbefore referred to and/or shown in the drawings whether or not particular emphasis has been placed thereon.

1. A method of forming a bulk, free-standing cubic III-N substrate comprising:
a) growing epitaxial III-N material on a cubic III-V substrate using molecular beam epitaxy (MBE); and
b) removing the III-V substrate to leave the III-N material as a bulk, free-standing cubic III-N substrate.

2. A method as claimed in claim 1, wherein step a) comprises:
a first initiation stage having a first set of MBE growth parameters including N-rich conditions; and
a second growth stage having a second set of different MBE growth parameters including N-rich conditions.

3. A method as claimed in claim 2, wherein the second set of MBE growth parameters has a higher temperature than the first set of MBE growth parameters.

4. A method as claimed in claim 2, wherein the second set of MBE growth parameters has a lower co-impinging Group V species flux than the first set of MBE growth parameters.

5. A method as claimed in claim 4, wherein the second set of MBE growth parameters has zero co-impinging Group V species flux.

6. A method as claimed in claim 2, wherein step a) comprises a third growth stage in which the ratio of supplied group III species to supplied N is used to control the growth rate.

7. A method as claimed in claim 6, wherein the ratio is slightly group III species-rich.

8. A method as claimed in claim 1, wherein step a) comprises controlling temperature, Group V species flux and a ratio of Group III species to N to avoid cracking of the deposited III-N material.

9. A method as claimed in claim 1, wherein step a) comprises controlling a ratio of Group III species to N so that N-rich conditions are maintained.

10. A method as claimed in claim 1, wherein step a) comprises controlling the temperature so that it is between 550 and 740° C.

11. A method as claimed in claim 1, wherein step b) comprises removing the III-V substrate using an etch.

12. A method as claimed in claim 1, further comprising after step b) polishing the surface of the bulk, free-standing cubic GaN substrate.

13. A method as claimed in claim 1 further comprising before step a) growing a III-V buffer layer on the III-V substrate.

14. A method as claimed in claim 1, wherein the III-V substrate is a cubic GaAs substrate.

15. A method as claimed in claim 1, wherein the III-N material is GaN.

16. A cubic III-N substrate formed by the method of claim 1.

17. A bulk, free-standing cubic III-N substrate for fabrication of III-N devices.

18. A substrate as claimed in claim 17, wherein the substrate is a cubic GaN substrate.

19. A substrate as claimed in claim 17, having a thickness greater than 5 μm

20. A substrate as claimed in 17, having an area greater than 1 cm²

21. A substrate as claimed in claim 17, wherein the substrate is a monocrystal.

22. A substrate as claimed in claim 17, wherein the substrate is non-composite.

23. A substrate as claimed in claim 17, wherein the substrate is undoped.

24. A substrate as claimed in claim 17, wherein the substrate is p-doped.

25. A substrate as claimed in claim 17, wherein the substrate is semi-insulating.

26. A substrate as claimed in claim 17, wherein the substrate is n-doped.

27. A photonic and/or electronic device comprising the substrate of claim 16.
